(19) United States
(12) Patent Application Publication
(10) Pub. No.: US 2026/0322335 A1
(43) Pub. Date: Oct. 15, 2026

(54) POWER AMPLIFIERS WITH DYNAMIC TEMPERATURE COMPENSATION

(71) Applicant: Skyworks Solutions, Inc., Irvine, CA (US)

(72) Inventors: Philip John Lehtola, Cedar Rapids, IA (US); Nathan Lucas Nuzum, Quasqueton, IA (US); Ajinkya Namdeorao More, Hiawatha, IA (US); Sarah Shihui Xu, Thousand Oaks, CA (US)

(21) Appl. No.: 19/573,583

(22) Filed: Mar. 20, 2026

Related U.S. Application Data
(60) Provisional application No. 63/787,169, filed on Apr. 11, 2025.

(51) Int. Cl. H03F 1/30; H03F 3/24

(52) U.S. Cl. CPC H03F 1/302; H03F 3/245; H03F 2200/447; H03F 2200/451

(57) ABSTRACT

Apparatus and methods for power amplifiers with dynamic temperature compensation are disclosed herein. In certain embodiments, a power amplifier includes one or more power amplifier stages for amplifying an RF signal, a bias circuit for generating a bias signal that biases at least one of the power amplifier stages, and a temperature compensation circuit that adjusts the bias signal based on a temperature difference between a first bipolar transistor operating at an ambient temperature and a second bipolar transistor operating at a temperature of a transistor array of the one or more power amplifier stages. Thus, the first and second bipolar transistors operate with a temperature difference that changes as the transistor array heats or cools.

### CROSS-REFERENCE TO RELATED APPLICATIONS

This application claims the benefit of priority under 35 U.S.C. § 119 of U.S. Provisional Patent Application No. 63/787169, filed Apr. 11, 2025, and titled “POWER AMPLIFIERS WITH DYNAMIC TEMPERATURE COMPENSATION,” each of which is herein incorporated by reference in its entirety.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for Fifth Generation (5G) cellular communications in Frequency Range 1 (FR1) or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and/or wearable electronics.

### SUMMARY

In certain embodiments, the present disclosure relates to a power amplifier. The power amplifier includes one or more power amplifier stages configured to amplify a radio frequency signal, the one or more power amplifier stages including a transistor array. The power amplifier further includes a bias circuit configured to generate a bias signal that biases at least one power amplifier stage of the power amplifier stages, and a temperature compensation circuit including a first bipolar transistor configured to operate at an ambient temperature and a second bipolar transistor configured to operate at a temperature of the transistor array, the temperature compensation circuit configured to adjust the bias signal based on a temperature difference between the first bipolar transistor and the second bipolar transistor.

In some embodiments, a base of the first bipolar transistor is electrically connected to a base and a collector of the second bipolar transistor at a node, and a collector of the first bipolar transistor is configured to provide a compensation current to the bias circuit. According to various embodiments, the temperature compensation circuit further includes a current source configured to provide a reference temperature compensation current to the node. In accordance with several embodiments, the reference temperature compensation current is controllable. According to a number of embodiments, the reference temperature compensation current is digitally controllable by at least one of registers or fuses. In accordance with several embodiments, the temperature compensation circuit further includes a low pass filter electrically connected to the node.

In various embodiments, the one or more power amplifier stages includes an input stage that is biased by the bias signal and an output stage that includes the transistor array.

In several embodiments, the first bipolar transistor and the second bipolar transistor are formed on a common semiconductor die and separated by at least 300 μm.

In some embodiments, the first bipolar transistor and the second bipolar transistor are formed on a common semiconductor die attached to a module substrate, and a layout of the first bipolar transistor is cooled by drawing heat through a separate electrical connection to the module substrate.

In several embodiments, the bias circuit includes a bias input node electrically connected to a collector of the first bipolar transistor, a reference bias current source configured to provide a reference bias current to the bias input node, and a first bias bipolar transistor having a base electrically connected to the bias input node and an emitter configured to generate the bias signal. According to a number of embodiments, a collector current of the first bipolar transistor is configured to adjust the reference bias current based on the temperature difference. In accordance with several embodiments, the bias circuit further includes a second bias bipolar transistor having a collector connected to the bias input node and an emitter electrically connected to a ground voltage, and a diode electrically connected between the bias input node and a base of the second bias bipolar transistor.

In various embodiments, the one or more power amplifier stages include a plurality of power amplifier stages arranged in a cascade.

In several embodiments, the one or more power amplifier stages include a plurality of power amplifier stages arranged as a push-pull power amplifier.

In some embodiments, a layout of the second bipolar transistor is integrated into a layout of the transistor array.

In certain embodiments, the present disclosure relates to a mobile device. The mobile device includes a transceiver configured to generate a radio frequency signal, and a front-end system including a power amplifier that includes one or more power amplifier stages configured to amplify the radio frequency signal, a bias circuit configured to generate a bias signal that biases at least one power amplifier stage of the power amplifier stages, and a temperature compensation circuit including a first bipolar transistor configured to operate at an ambient temperature and a second bipolar transistor configured to operate at a temperature of a transistor array of the one or more power amplifier stages. The temperature compensation circuit is configured to adjust the bias signal based on a temperature difference between the first bipolar transistor and the second bipolar transistor.

In some embodiments, a base of the first bipolar transistor is electrically connected to a base and a collector of the second bipolar transistor at a node, and a collector of the first bipolar transistor is configured to provide a compensation current to the bias circuit. In accordance with a number of embodiments, the temperature compensation circuit further includes a current source configured to provide a reference temperature compensation current to the node. According to several embodiments, the reference temperature compensation current is controllable. In accordance with various embodiments, the reference temperature compensation current is digitally controllable by at least one of registers or fuses. According to a number of embodiments, the temperature compensation circuit further includes a low pass filter electrically connected to the node.

In various embodiments, the one or more power amplifier stages includes an input stage that is biased by the bias signal and an output stage that includes the transistor array.

In several embodiments, the first bipolar transistor and the second bipolar transistor are formed on a common semiconductor die and separated by at least 300 μm.

In some embodiments, the first bipolar transistor and the second bipolar transistor are formed on a common semiconductor die attached to a module substrate, and a layout of the first bipolar transistor is cooled by drawing heat through a separate electrical connection to the module substrate.

In various embodiments, the bias circuit includes a bias input node electrically connected to a collector of the first bipolar transistor, a reference bias current source configured to provide a reference bias current to the bias input node, and a first bias bipolar transistor having a base electrically connected to the bias input node and an emitter configured to generate the bias signal. According to a number of embodiments, a collector current of the first bipolar transistor is configured to adjust the reference bias current based on the temperature difference. In accordance with several embodiments, the bias circuit further includes a second bias bipolar transistor having a collector connected to the bias input node and an emitter electrically connected to a ground voltage, and a diode electrically connected between the bias input node and a base of the second bias bipolar transistor.

In some embodiments, the one or more power amplifier stages include a plurality of power amplifier stages arranged in a cascade.

In various embodiments, the one or more power amplifier stages include a plurality of power amplifier stages arranged as a push-pull power amplifier.

In several embodiments, a layout of the second bipolar transistor is integrated into a layout of the transistor array.

In some embodiments, the mobile device further includes an antenna configured to transmit an amplified radio frequency signal outputted by the power amplifier.

In certain embodiments, the present disclosure relates to a method of radio frequency signal amplification in a mobile device. The method includes amplifying a radio frequency signal using one or more power amplifier stages of a power amplifier, the one or more power amplifier stages including a transistor array. The method further includes generating a bias signal that biases at least one power amplifier stage of the power amplifier stages using a bias circuit of the power amplifier. The method further includes operating a first bipolar transistor of a temperature compensation circuit of the power amplifier at an ambient temperature, and operating a second bipolar transistor of the power amplifier at a temperature of the transistor array. The method further includes adjusting the bias signal based on a temperature difference between the first bipolar transistor and the second bipolar transistor using the temperature compensation circuit.

In some embodiments, a base of the first bipolar transistor is electrically connected to a base and a collector of the second bipolar transistor at a node, the method further comprising providing a compensation current to the bias circuit from a collector of the first bipolar transistor. According to a number of embodiments, the method further includes providing a reference temperature compensation current to the node from a current source. In accordance with several embodiments, the method further includes controlling a current level of the reference temperature compensation current. According to various embodiments, the method further includes digitally setting the current level of the reference temperature compensation current using at least one of registers or fuses. In accordance with a number of embodiments, the method further includes providing low pass filtering using a low pass filter electrically connected to the node.

In various embodiments, the one or more power amplifier stages includes an input stage that is biased by the bias signal and an output stage that includes the transistor array.

In several embodiments, the first bipolar transistor and the second bipolar transistor are formed on a common semiconductor die and separated by at least 300 μm.

In some embodiments, the first bipolar transistor and the second bipolar transistor are formed on a common semiconductor die attached to a module substrate, and a layout of the first bipolar transistor is cooled by drawing heat through a separate electrical connection to the module substrate.

In various embodiments, the bias circuit includes a bias input node electrically connected to a collector of the first bipolar transistor, a reference bias current source configured to provide a reference bias current to the bias input node, and a first bias bipolar transistor having a base electrically connected to the bias input node and an emitter configured to generate the bias signal. According to several embodiments, a collector current of the first bipolar transistor is configured to adjust the reference bias current based on the temperature difference. According to a number of embodiments, the bias circuit further includes a second bias bipolar transistor having a collector connected to the bias input node and an emitter electrically connected to a ground voltage, and a diode electrically connected between the bias input node and a base of the second bias bipolar transistor.

In some embodiments, the one or more power amplifier stages include a plurality of power amplifier stages arranged in a cascade.

In various embodiments, the one or more power amplifier stages include a plurality of power amplifier stages arranged as a push-pull power amplifier.

In several embodiments, a layout of the second bipolar transistor is integrated into a layout of the transistor array.

In some embodiments, the method further includes transmitting an amplified radio frequency signal outputted by the power amplifier using an antenna.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is a schematic diagram of one example of an uplink channel using MIMO communications.

FIG. 3C is a schematic diagram of another example of an uplink channel using MIMO communications.

FIG. 4 is a schematic diagram of an example dual connectivity network topology.

FIG. 5A is a schematic diagram of a power amplifier according to one embodiment.

FIG. 5B is a schematic diagram of a power amplifier according to another embodiment.

FIG. 5C is a schematic diagram depicting one embodiment of dynamic temperature compensation for the power amplifier of FIG. 5B.

FIG. 6A is a schematic diagram of a power amplifier according to another embodiment.

FIG. 6B is a plan view of one embodiment of a power amplifier transistor array for the power amplifier of FIG. 6A.

FIG. 6C is a plan view of one embodiment of a power amplifier transistor array for the power amplifier of FIG. 6A.

FIG. 7A is a plan view of an RF module according to one embodiment.

FIG. 7B is a cross-section of the RF of FIG. 7A taken along the lines 7A-7A.

FIG. 8 a graph of one example of current versus temperature for a temperature compensation circuit providing dynamic temperature compensation (DTC).

FIG. 9A is a schematic diagram of one embodiment of a reference current control circuit.

FIG. 9B is a schematic diagram of another embodiment of a reference current control circuit.

FIG. 10 depicts examples of various graphs of temperature dependent characteristics for two levels of the reference temperature compensation current.

FIG. 11A depicts one example of gain versus measured output power for a power amplifier.

FIG. 11B depicts one example of servo error versus measured output power for a power amplifier.

FIG. 11C depicts one example of amplitude distortion (AMAM) versus measured output power for a power amplifier.

FIG. 11D depicts one example of phase versus measured output power for a power amplifier.

FIG. 11E depicts one example of power added efficiency (PAE) versus measured output power for a power amplifier.

FIG. 11F depicts one example of adjacent channel leakage ratio (ALCR1) versus measured output power for a power amplifier.

FIG. 11G depicts one example of maximum power reduction (MPR3) and ACLR1 versus temperature difference.

FIG. 12 is a schematic diagram of one embodiment of a mobile device.

FIG. 13 is a schematic diagram of a power amplifier system according to one embodiment.

FIG. 14 is a graph of one example of measured gain versus output power for various duty cycles with and without DTC.

FIG. 15 is a graph of one example of measured ALCR1 versus frequency with DTC.

FIG. 16A is one example of a set of waterfall curves of gain versus output power without DTC.

FIG. 16B is one example of a set of waterfall curves of gain versus output power with DTC.

FIG. 17 is a graph of one example of power versus time for various DTC levels.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE). 3GPP introduced Phase 1 of fifth generation (5G) technology in Release 15 and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

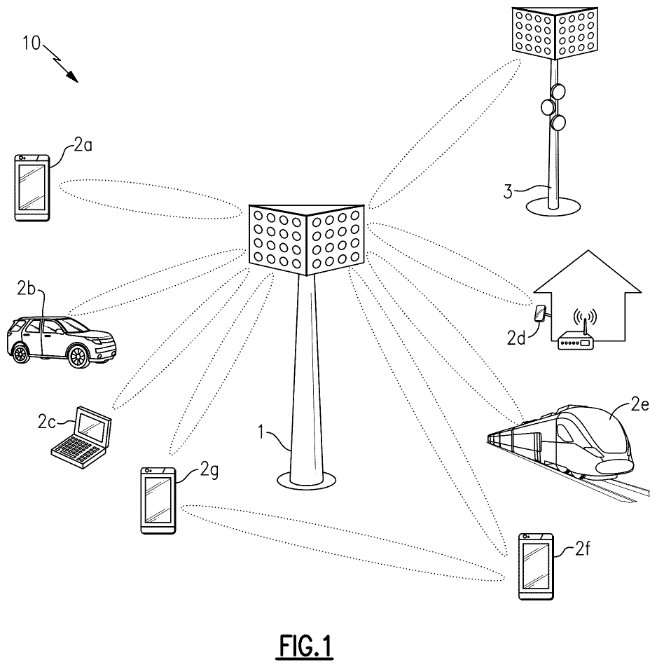

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as Wi-Fi®. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and Wi-Fi® technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed Wi-Fi® frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

In certain implementations, the communication network 10 supports supplementary uplink (SUL) and/or supplementary downlink (SDL). For example, when channel conditions are good, the communication network 10 can direct a particular UE to transmit using an original uplink frequency, while when channel condition is poor (for instance, below a certain criteria) the communication network 10 can direct the UE to transmit using a supplementary uplink frequency that is lower than the original uplink frequency. Since cell coverage increases with lower frequency, communication range and/or signal-to-noise ratio (SNR) can be increased using SUL. Likewise, SDL can be used to transmit using an original downlink frequency when channel conditions are good, and to transmit using a supplementary downlink frequency when channel conditions are poor.

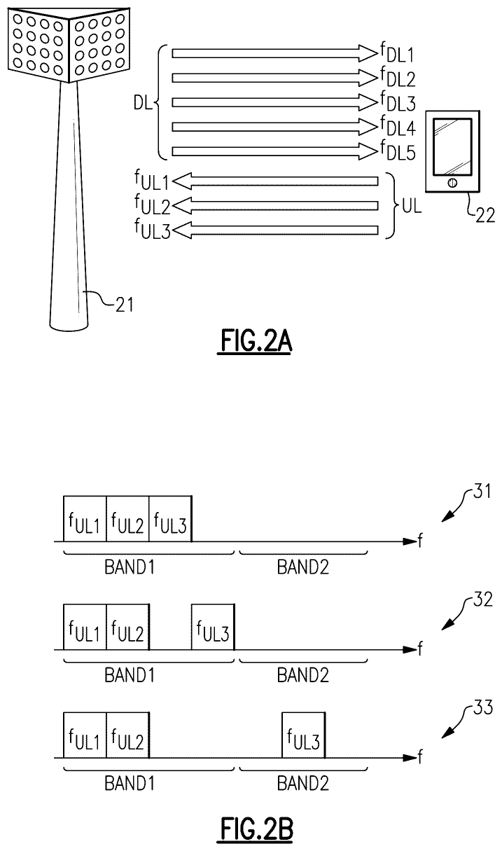

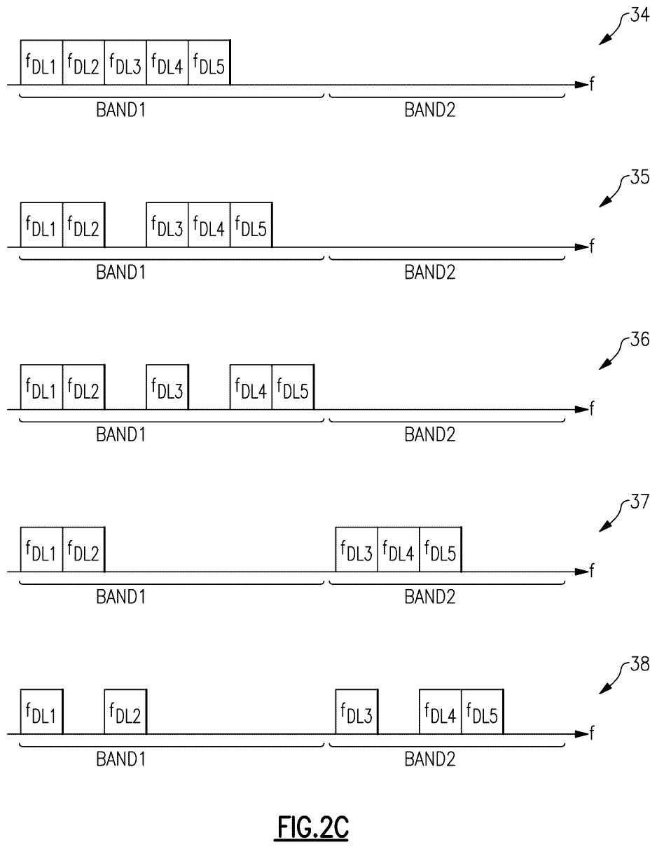

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as Wi-Fi®. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid Wi-Fi® users and/or to coexist with Wi-Fi® users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

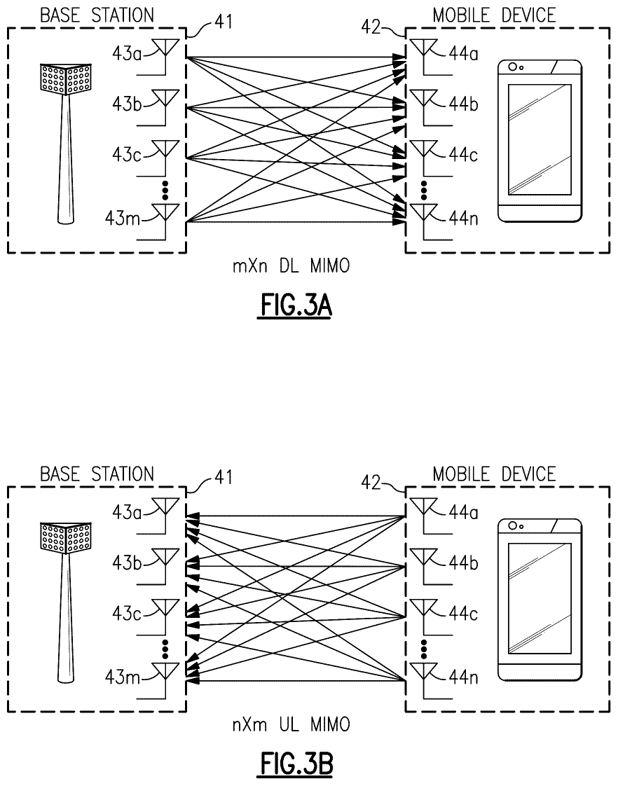

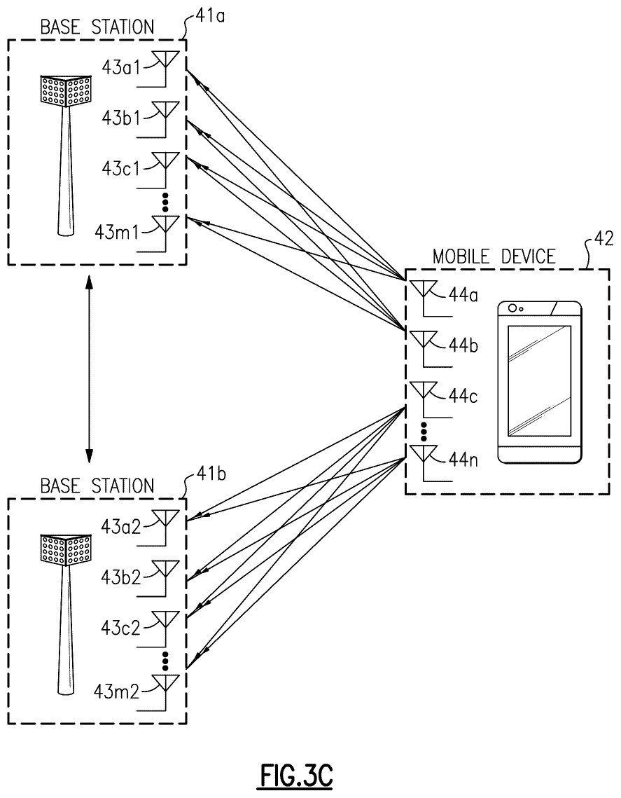

FIG. 3A is a schematic diagram of one example of a downlink channel using multi-input and multi-output (MIMO) communications. FIG. 3B is a schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m x n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is a schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

With the introduction of the 5G NR air interface standards, 3GPP has allowed for the simultaneous operation of 5G and 4G standards in order to facilitate the transition. This mode can be referred to as Non-Stand-Alone (NSA) operation or E-UTRAN New Radio-Dual Connectivity (EN-DC) and involves both 4G and 5G carriers being simultaneously transmitted from user equipment (UE).

In certain EN-DC applications, dual connectivity NSA involves overlaying 5G systems onto an existing 4G core network. For dual connectivity in such applications, the control and synchronization between the base station and the UE can be performed by the 4G network while the 5G network is a complementary radio access network tethered to the 4G anchor. The 4G anchor can connect to the existing 4G network with the overlay of 5G data/control.

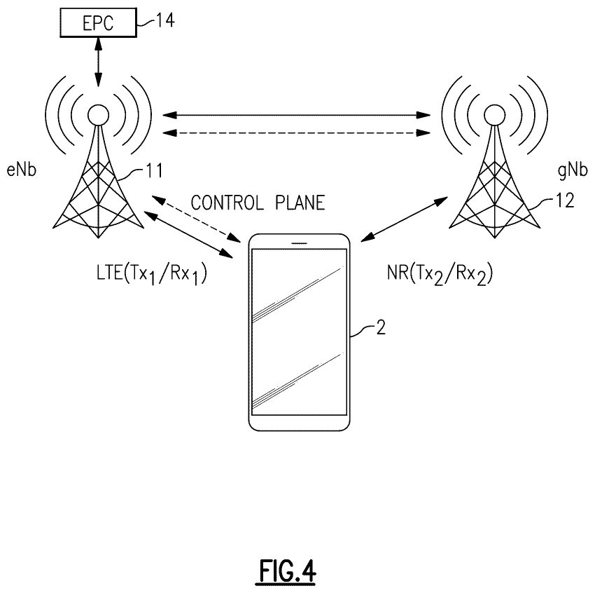

FIG. 4 is a schematic diagram of an example dual connectivity network topology. This architecture can leverage LTE legacy coverage to ensure continuity of service delivery and the progressive rollout of 5G cells. A UE 2 can simultaneously transmit dual uplink LTE and NR carrier. The UE 2 can transmit an uplink LTE carrier Tx1 to the eNB 11 while transmitting an uplink NR carrier Tx2 to the gNB 12 to implement dual connectivity. Any suitable combination of uplink carriers Tx1, Tx2 and/or downlink carriers Rx1, Rx2 can be concurrently transmitted via wireless links in the example network topology of FIG. 1. The eNB 11 can provide a connection with a core network, such as an Evolved Packet Core (EPC) 14. The gNB 12 can communicate with the core network via the eNB 11. Control plane data can be wireless communicated between the UE 2 and eNB 11. The eNB 11 can also communicate control plane data with the gNB 12. Control plane data can propagate along the paths of the dashed lines in FIG. 4. The solid lines in FIG. 4 are for data plane paths.

In the example dual connectivity topology of FIG. 4, any suitable combinations of standardized bands and radio access technologies (e.g., FDD, TDD, SUL, SDL) can be wirelessly transmitted and received. This can present technical challenges related to having multiple separate radios and bands functioning in the UE 2. With a TDD LTE anchor point, network operation may be synchronous, in which case the operating modes can be constrained to Tx1/Tx2 and Rx1/Rx2, or asynchronous which can involve Tx1/Tx2, Tx1/Rx2, Rx1/Tx2, Rx1/Rx2. When the LTE anchor is a frequency division duplex (FDD) carrier, the TDD/FDD inter-band operation can involve simultaneous Tx1/Rx1/Tx2 and Tx1/Rx1/Rx2.

As discussed above, EN-DC can involve both 4G and 5G carriers being simultaneously transmitted from a UE. Transmitting both 4G and 5G carriers in a UE, such as a phone, typically involves two power amplifiers (PAs) being active at the same time. Traditionally, having two power amplifiers active simultaneously would involve the placement of one or more additional power amplifiers specifically suited for EN-DC operation. Additional board space and expense are incurred when designing to support such EN-DC/NSA operation.

### Examples of Features Supported by RRRE Systems Including Power Amplifiers

A radio frequency (RF) communication device can include multiple antennas for supporting wireless communications. Additionally, the RF communication device can include a radio frequency front-end (RFFE) system for processing signals received from and transmitted by the antennas. The RFFE system can provide a number of functions, including, but not limited to, signal filtering, signal partitioning and combining, controlling component connectivity to the antennas, and/or signal amplification.

RFFE systems can be used to handle RF signals of a wide variety of types, including, but not limited to, wireless local area network (WLAN) signals, Bluetooth® signals, and/or cellular signals. RFFE systems are also referred to herein as front-end systems.

RFFE systems can be used to process signals of a wide range of frequencies. For example, certain RFFE systems can operate using one or more low bands (for example, RF signal bands having a frequency content of 1 GHz or less, also referred to herein as LB), one or more mid bands (for example, RF signal bands having a frequency content between 1 GHz and 2.3 GHz, also referred to herein as MB), one or more high bands (for example, RF signal bands having a frequency content between 2.3 GHz and 3 GHz, also referred to herein as HB), and one or more ultrahigh bands (for example, RF signal bands having a frequency content between 3 GHz and 7.125 GHz, also referred to herein as UHB). In certain implementations, modules operate over mid band and high band frequencies (MHB).

Moreover, RFFE systems can also process millimeter wave frequency signals, such as those in FR2 of 5G.

RFFE systems can be used in a wide variety of RF communication devices, including, but not limited to, smartphones, base stations, laptops, handsets, wearable electronics, and/or tablets.

An RFFE system can be implemented to support a variety of features that enhance bandwidth and/or other performance characteristics of the RF communication device in which the RFFE system is incorporated.

For example, to support wider bandwidth, an increasing number of uplink carrier aggregation scenarios have been developed to support wider bandwidth. Additionally, the bandwidths for uplink and downlink cannot be arbitrarily sent since there is a minimum uplink bandwidth for maintaining a reliable link supported by the transport layer's ACK/NACK traffic. Thus, in 4G/5G, wideband uplink carrier aggregation should be supported to achieve higher bandwidth for downlink carrier aggregation.

Thus, an RFFE system can be implemented to support both uplink and downlink carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels, for instance up to five carriers. Carrier aggregation includes contiguous aggregation, in which contiguous carriers within the same operating frequency band are aggregated. Carrier aggregation can also be non-contiguous, and can include carriers separated in frequency within a common band or in different bands.

Transition from 4G to 5G is through non-standalone (NSA) operation, rather than directly to full standalone (SA) operation. Current networks operate in 4G and 5G concurrently by communicating with an eNodeB and a gNodeB simultaneously in an EN-DC mode of operation. Thus, 4G and 5G transmitters operate concurrently is such a phone.

To provide such feature support, an RFFE system can be implemented to support EN-DC.

Support for EN-DC can cover a wide range of frequency bands, including using a 4G band in the LB, MHB, HB, or UHB frequency ranges in combination with a 5G band in the LB, MHB, HB, or UHB frequency ranges. Thus, various combinations of EN-DC including, but not limited to, LB-LB EN-DC, MHB-MHB EN-DC, LB-MHB EN-DC, LB-UHB EN-DC, MHB-UHB EN-DC, and/or UHB-UHB EN-DC, are possible.

Moreover, in certain dual uplink transmission scenarios, it can be desirable to provide flexibility between swapping which antenna transmits a first RF transmit signal (for instance, one of a 4G signal or a 5G signal) on a first side of a phone board assembly and which antenna transmits a second RF transmit signal (for instance, the other of the 4G signal or the 5G signal) on a side of the phone board assembly. To provide such flexibility, an RFFE system can support a transmit swap function to selectively switch which antenna a particular RF transmit signal is transmitted from.

Another technique for increasing uplink capacity is uplink multiple-input multiple-output (MIMO) communications, in which multiple (for instance, two) power amplifiers transmit two different signals simultaneously on the same frequency using different antennas. MIMO communications benefit from higher signal to noise ratio, improved coding, and/or reduced signal interference due to spatial multiplexing differences of the radio environment. MIMO order refers to the number of separate data streams sent or received.

### Example Embodiments of Power Amplifiers With Dynamic Temperature Compensation

Constraints on power amplifier linearity and efficiency continue to tighten with evolving radio communications specifications. Thus, it is desirable for a power amplifier to have linear gain versus output power and linear phase versus output power characteristics. For example, it is desirable for power amplifiers to have little to no amplitude distortion (AMAM) and phase distortion (AMPM). Achieving linear gain and phase characteristics while maintaining output power and efficiency is a key challenge in power amplifier design.

Accordingly, a perfect power amplifier should have gain that is invariant to thermal effects. However, power dissipation in the power amplifier's transistor devices increases junction temperature and lowers gain, which in turn degrades the power amplifier's linearity. For example, a power amplifier calibrated at a predetermined average power level will behave differently at other average power levels due to variation in junction temperature and consequently gain.

Apparatus and methods for power amplifiers with dynamic temperature compensation are disclosed herein. In certain embodiments, a power amplifier includes one or more power amplifier stages for amplifying an RF signal, a bias circuit for generating a bias signal that biases at least one of the power amplifier stages, and a temperature compensation circuit that adjusts the bias signal based on a temperature difference between a first bipolar transistor operating at an ambient temperature and a second bipolar transistor operating at a temperature of a transistor array of the one or more power amplifier stages. Thus, the first and second bipolar transistors operate with a temperature difference that changes as the transistor array heats or cools.

By providing dynamic temperature compensation in this manner, non-linearities arising from thermal effects are compensated for. For example, adjusting the bias signal in accordance with the transistor array temperature improves overall linearity and reduces sensitivity in adjacent channel leakage ratio (ACLR) to temperature.

In certain implementations, the bias signal (for instance, a current and/or a voltage bias) of a first power amplifier stage of the power amplifier stages, while the transistor array is included in a second power amplifier stage of the power amplifier stages.

For example, the first power amplifier stage can correspond to an input stage (also referred to herein as a driver stage) while the second power amplifier stage can correspond to an output stage. Since the transistor array of the output stage typically operates at the hottest temperature of the power amplifier, such a compensation scheme can accurately track the power amplifier's operating temperature over time while providing bias adjustments earlier in the amplification chain.

In certain implementations, the second bipolar transistor is integrated into a transistor array of a heterojunction bipolar transistor (HBT) and is used to detect the base-emitter junction temperature of the HBT.

Various cooling techniques can be used to cool the first bipolar transistor and maintain operation at ambient temperature. In one example, the first bipolar transistor is placed far from the second bipolar transistor (for instance, distance of 300 μm or more) on a semiconductor die. In another example, a layout of the first bipolar transistor can be placed next to a dedicating ground bump of the semiconductor die that connects to separate metallization of an MCM, thereby providing an effective thermal mechanism to draw heat away from the first bipolar transistor.

In certain implementations, the base of the first bipolar transistor is electrically connected to the base and the collector of the second bipolar transistor at a node that receives a reference temperature compensation current. As the temperature difference between the first and second bipolar transistors changes, an adjustment current at a collector of the first bipolar transistor changes in relation to the temperature difference. The adjustment current can be used to adjust a reference current of the bias circuit to thereby control the bias signal level.

To improve noise performance, the temperature compensation circuit can include a low pass filter electrically connected to the bases of the first and second bipolar transistors.

In certain implementations, the reference temperature compensation current is controllable (for instance, digitally controllable by registers and/or fuses) to provide flexibility in setting the degree of sensitivity of the compensation to temperature changes.

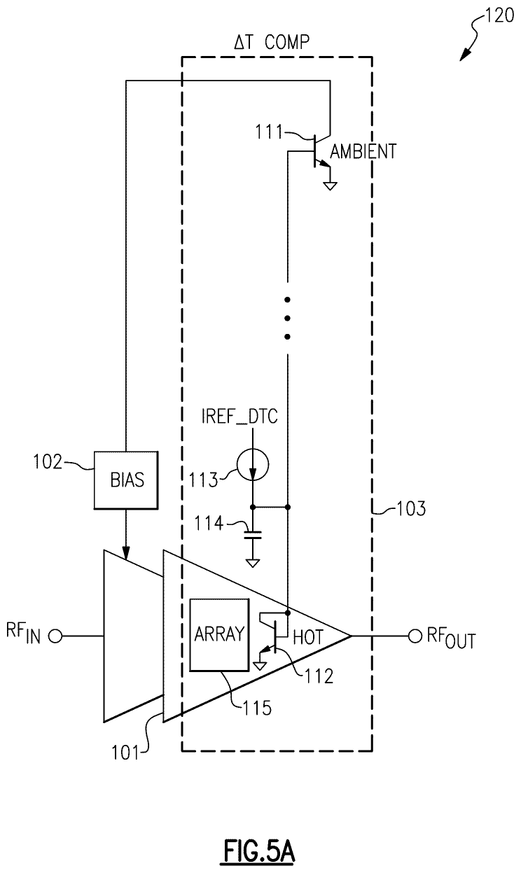

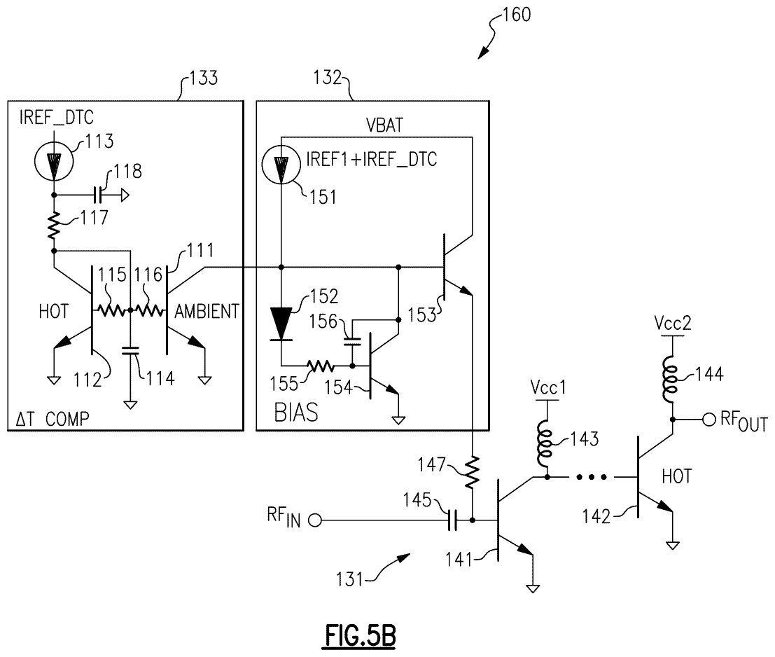

FIG. 5A is a schematic diagram of a power amplifier 120 according to one embodiment. The power amplifier 120 includes an RF input RF_{IN} that receives an RF signal and an RF output RF_{OUT} that provides an amplified RF signal. The power amplifier 120 further includes one or more power amplifier stages 101 for amplifying the RF signal, a bias circuit 102 for generating a bias signal that biases at least one of the power amplifier stages 101, and a temperature compensation circuit 103.

As shown in FIG. 5A, the one or more power amplifier stages 101 includes a transistor array 102 (for example, an array implementing a layout of an HBT) for providing application to the RF signal. In certain implementations, the transistor array 102 is part of an output stage of the power amplifier 120.

In the illustrated embodiment, the temperature compensation circuit 103 includes a first bipolar transistor 111, a second bipolar transistor 112, a current source 113, and a capacitor 114. The first bipolar transistor 111 includes a base electrically connected to a base and a collector of the second bipolar transistor 112 at a node that receives a reference temperature compensation current IREF_DTC from the current source 113. The emitters of the first bipolar transistor 111 and the second bipolar transistor 112 are electrically connected to a ground voltage, while the capacitor 114 is electrically connected between the node and the ground voltage.

With continuing reference to FIG. 5A, the first bipolar transistor 111 operates at an ambient temperature while the second bipolar transistor 112 is placed in or near the transistor array 115 to operate at a temperature of the transistor array 115. In one example, the second bipolar transistor 112 is integrated into the transistor array 115. In a second example, the second bipolar transistor 112 is placed within 20 μm of the transistor array 115.

As shown in FIG. 5A, the first bipolar transistor 111 and the second bipolar transistor 112 are physically separated to operate at different temperatures. In certain implementations, the first bipolar transistor 111 and the second bipolar transistor 112 are formed on a common die but separated in layout by at least 300 μm.

The temperature compensation circuit 103 serves to adjust the bias signal provided by the bias circuit 102 based on a temperature difference (ΔT) between the first bipolar transistor 111 operating at the ambient temperature and the second bipolar transistor 112 operating at the hot temperature of the transistor array 115. Thus, the first bipolar transistor 111 and the second bipolar transistor 112 operate with a temperature difference that changes as the transistor array 115 heats or cools, and the temperature difference controls the collector current of the first bipolar transistor 111 to adjust the bias signal level from the bias circuit 102.

By providing dynamic temperature compensation in this manner, non-linearities arising from thermal effects are compensated for. For example, adjusting the bias signal in accordance with the temperature of the transistor array 115 improves overall linearity and reduces sensitivity in ACLR to temperature.

In certain implementations, the one or more power amplifier stages 101 includes an input or driver power amplifier stage that is biased by the bias signal and an output power amplifier stage that includes the transistor array 115. Such a configuration provides accurate junction temperature detection of the power amplifier 120 while providing robust stability against thermal runaway.

The current source 113 provides the reference temperature compensation current IREF_DTC, which controls the sensitivity of the temperature compensation circuit 103 to the transistor temperature difference. In certain implementations, the current source 113 is controllable. For example, the reference temperature compensation current IREF_DTC is digitally controllable by registers or fuses to set an appropriate level of sensitivity to the difference in temperature between the first bipolar transistor 111 and the second bipolar transistor 112.

The capacitor 114 can serve in part to provide low pass filtering that can reject noise, such as RF noise arising from RF signal amplification that couples into the temperature compensation circuit 103. Although shown as a single capacitor, in certain implementations the capacitor 114 is partitioned into two or more capacitors that are distributed along the electrical connection between the base of the first bipolar transistor 111 and the base of the second bipolar transistor 112. Such capacitance distribution can provide local filtering near the transistor bases for improved performance. In one example, one half of the capacitance is placed near the base of the first bipolar transistor 111 while another half of the capacitance is placed near the base of the second bipolar transistor 112. In certain implementations, the capacitor 114 operates in combination with explicit resistors and/or parasitic resistances of conductors to provide low pass resistor-capacitor (RC) filtering.

FIG. 5B is a schematic diagram of a power amplifier 160 according to another embodiment. The power amplifier 160 includes an RF input RF_{IN} that receives an RF signal and an RF output RF_{OUT} that provides an amplified RF signal. The power amplifier 160 further includes two or more power amplifier stages 131 for amplifying the RF signal, a bias circuit 132 for generating a bias signal that biases an input power amplifier stage of the power amplifier stages 131, and a temperature compensation circuit 133.

In the illustrated embodiment, the input power amplifier stage includes an input stage HBT 141, an input stage choke inductor 143 for providing a first power amplifier supply voltage Vcc1 to a collector of the input stage HBT 141, a DC blocking capacitor 145 for providing DC voltage blocking between the RF input RF_{IN} and the base of the input stage HBT 141, and an input stage resistor 147 for providing the bias signal from the bias circuit 132 to the base of the input stage HBT 141. The output power amplifier stage includes an output stage HBT 142 and an output stage choke inductor 144 for providing a second power amplifier supply voltage Vcc2 to a collector of the output stage HBT 142. The output stage HBT 142 is implemented in layout using a transistor array that has a hot temperature during operation.

With continuing reference to FIG. 5B, the temperature compensation circuit 133 includes a first bipolar transistor 111, a second bipolar transistor 112, a current source 113, a first capacitor 114, a first resistor 115, a second resistor 116, a third resistor 117, and a second capacitor 118. The first bipolar transistor 111 operates at an ambient temperature while the second bipolar transistor 112 operates at the temperature of the transistor array of the output stage HBT 142. For clarity of the figure, the proximity of the second bipolar transistor 112 to the transistor array of the output stage HBT 142 is not depicted in this figure.

The temperature compensation circuit 133 of FIG. 5B is similar to the temperature compensation circuit 103 of FIG. 5A, except that the temperature compensation circuit 133 of FIG. 5B depicts an example of additional resistor and capacitor components for providing noise filtering.

In the illustrated embodiment, the bias circuit 132 includes a reference bias current source 151, a bias diode 152, a first bias bipolar transistor 153, a second bias bipolar transistor 154, a resistor 155, and a capacitor 156. The collector of the first bias bipolar transistor 153 receives a battery voltage VBAT, the emitter of the first bias bipolar transistor 153 generates the bias signal, and the base of the first bias bipolar transistor 153 is connected to a bias input node. The diode 152 and resistor 155 are connected in series between the bias input node and the base of the second bias bipolar transistor 154. The emitter of the second bias bipolar transistor 154 is connected to the ground voltage, while the collector of the second bias bipolar transistor 154 is connected to the bias input node. The capacitor 156 is connected between the base and the collector of the second bias bipolar transistor 154. The reference bias current source 151 provides a reference current (of value IREF1+IREF_DTC, in this example) to the bias input node.

The collector current generated by the first bipolar transistor 111 changes in relation to a temperature difference between the first bipolar transistor 111 (ambient) and the second bipolar transistor 112 (hot during power amplifier operation). Additionally, the collector current provides an adjustment to the reference current level of the bias circuit 132 to dynamically compensate for temperature.

For example, FIG. 5C is a schematic diagram depicting one embodiment of dynamic temperature compensation for the power amplifier 160 of FIG. 5B.

With reference to FIGS. 5B and 5C, bipolar transistor collector current ICC is equal to Is*(e^VBE/Vt−1), where Is corresponds to transistor saturation current, VBE to base-to-emitter voltage, and Vt to thermal voltage. Is is proportional to temperature in bipolar devices. For a constant IREF_HOT through the second bipolar transistor 112, as the device gets hotter VBE drops to compensate for increase in Is.

Accordingly, an increase in temperature causes VBE to drop. Additionally, the drop in VBE reduces the current IREF_AMBIENT. This in turn effectively increases the reference current of the bias circuit 132 (effective IREF1). For example, effective IREF1 increases since we are adding IREF_DTC to IREF1 but subtracting a smaller value (IREF_AMBIENT) from IREF1. Higher effective IREF1 increases the ICC of the input power amplifier stage and boosts gain.

Thus, the temperature compensation circuit operates to steal IREF_AMBIENT from the reference current of the bias circuit 132 (IREF1+IREF_DTC) to generate an effective IREF1. When the first bipolar transistor 111 and the second bipolar transistor 112 operate at the same temperature then IREF_AMBIENT =IREF_DTC and effective IREF1=IREF1. However, when the second bipolar transistor 112 gets hotter than the first bipolar transistor 111, IREF_AMBIENT reduces and effective IREF1 goes up. Additionally, the maximum effective IREF1=IREF1+IREF_DTC, which occurs when IREF_AMBIENT becomes zero.

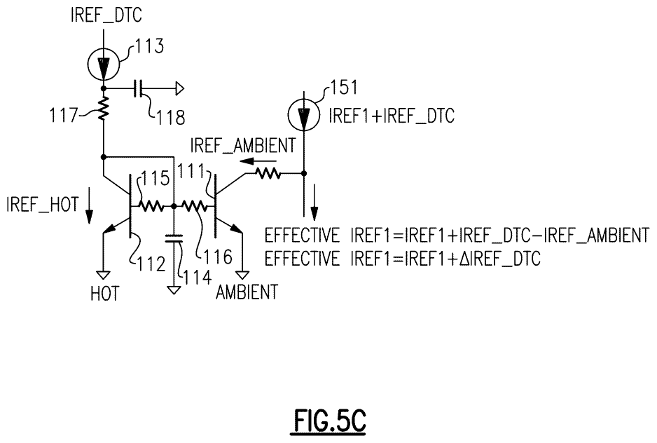

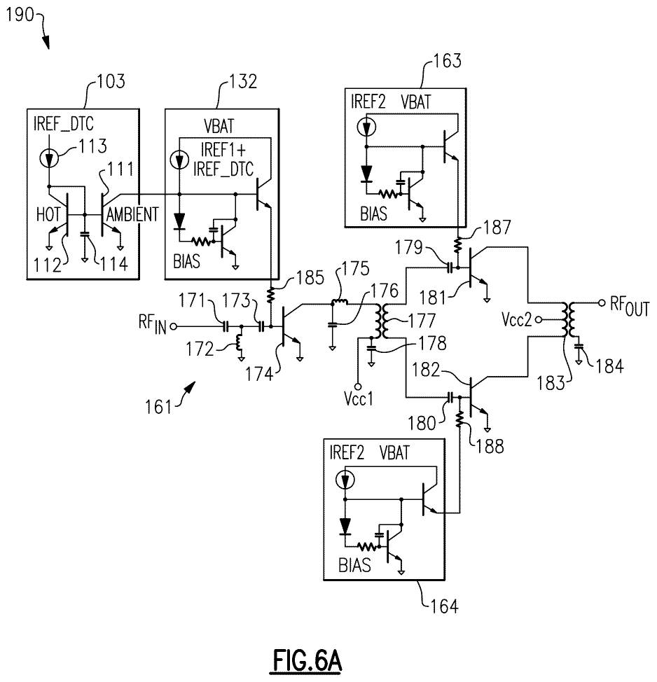

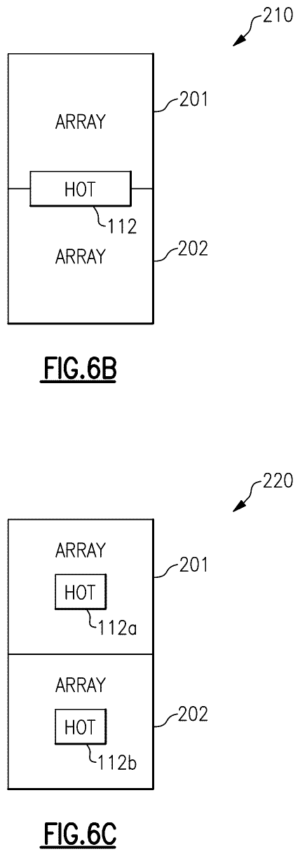

FIG. 6A is a schematic diagram of a power amplifier 190 according to another embodiment. The power amplifier 190 includes an RF input RF_{IN} that receives an RF signal and an RF output RF_{OUT} that provides an amplified RF signal. The power amplifier 190 further includes push-pull power amplifier stages 161 for amplifying the RF signal, an input bias circuit 132 for generating a bias signal for an input stage of the push-pull power amplifier stages 161, a first output bias circuit 163 that biases a first output stage of the push-pull power amplifier stages 161, a second output bias circuit 164 that biases a second output stage of the push-pull power amplifier stages 161, and a temperature compensation circuit 103.

With reference to FIG. 6A, the input stage of the push-pull power amplifier stages 161 includes a first series capacitor 171, a shunt inductor 172, a second series capacitor 173, an input stage HBT 174, a series inductor 175, a shunt capacitor 176, a first balun 177, a balun termination capacitor 178, and an input stage bias resistor 185. Additionally, the collector of the input stage HBT 174 receives a first power supply voltage Vcc1 through a first winding of the first balun 177.

As shown in FIG. 6A, the first output stage of the push-pull power amplifier stages 161 includes a first series capacitor 179, a first output stage HBT 181, and a first output stage bias resistor 187. Furthermore, the second output stage of the push-pull power amplifier stages 161 includes a second series capacitor 180, a second output stage HBT 182, and a second output stage bias resistor 188. The output signals of the output stages are combined using an output balun 183 that includes a first winding electrically connected between the collectors of the output stage HBTs 181/182 and a second winding electrically connected between the RF output RF_{OUT} and an output stage termination capacitor 184. The collectors of the output stage HBTs 181/182 receive a second power supply voltage Vcc2 by way of a center tap of a first winding of the output balun 183.

In the illustrated embodiment, the temperature compensation circuit 103 detects a temperature difference between ambient temperature and a junction temperature of the output stage HBTs 181/182. Additionally, the compensation current generated by the temperature compensation circuit 103 is used to adjust the bias signal to the input stage HBT 174.

The power amplifier 190 of FIG. 6A depicts an example of dynamic temperature compensation for a push-pull power amplifier. The dynamic temperature compensation schemes herein are applicable to a wide range of power amplifiers, including power amplifiers that include a cascade of two or more stages, push-pull power amplifiers, Doherty power amplifiers, and/or other suitable power amplifier topologies.

FIG. 6B is a plan view of one embodiment of a power amplifier transistor array 210 for the power amplifier 210 of FIG. 6A. The power amplifier transistor array 210 includes a first transistor sub-array 201 for the first output stage HBT 181 and a second transistor sub-array 202 for the second output stage HBT 182. Additionally, a layout for the second bipolar transistor 112 is placed along a boundary between the transistor sub-arrays 201/202.

FIG. 6C is a plan view of one embodiment of a power amplifier transistor array 220 for the power amplifier 210 of FIG. 6A. The power amplifier transistor array 220 includes a first transistor sub-array 201 for the first output stage HBT 181 and a second transistor sub-array 202 for the second output stage HBT 182. Additionally, a first portion 112a of the layout for the second bipolar transistor 112 is placed in the first transistor sub-array 201, while a second portion 112b of the layout for the second bipolar transistor 112 is placed in the second transistor sub-array 202.

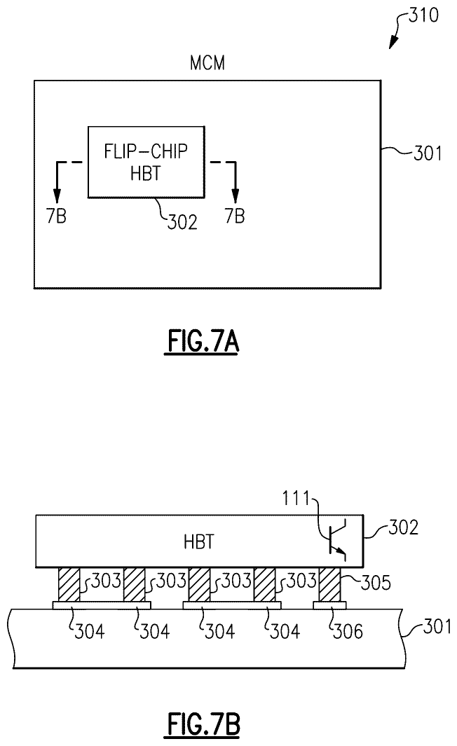

FIG. 7A is a plan view of an RF module 310 according to one embodiment. FIG. 7B is a cross-section of the RF module 310 of FIG. 7A taken along the lines 7A-7A.

With reference to FIGS. 7A and 7B, the RF module 310 includes a module substrate 301 and an HBT die 302 attached to the module substrate 301 (by a flip-chip mounting, in this example). Although not shown in FIGS. 7A and 7B, the RF module 310 can include additional semiconductor dies, surface mount components, pins, and/or other structures as desired. For example, the RF module 310 can be implemented as a multi-chip module (MCM) with multiple semiconductor dies and SMT components attached to the substrate 301.

The HBT die 302 can be implemented to include any of the power amplifiers disclosed herein. As shown in FIG. 7B, various pads of the HBT die 302 connect to metal pads 304 on the module substrate 301 by way of copper pillars 303. Additionally, a layout of the first bipolar transistor 111 is placed on a portion of the HBT die 302 associated with a separate copper pillar 305 and a separate metal pad 306 on the module substrate 301. In one example, the layout of the first bipolar transistor 111 is vertically aligned with the separate copper pillar 305.

In certain implementations, the separate metal pad 306 can correspond to a ground bump that is at ground voltage potential but that does not connect to other ground conductors on the HBT die 302.

The separate copper pillar 305 and separate metal pad 306 provide a mechanism to pull heat away from the first bipolar transistor 111 thereby providing cooling that helps to operate the first bipolar transistor 111 at ambient temperature.

FIG. 8 a graph of one example of current versus temperature for a temperature compensation circuit providing dynamic temperature compensation. The graph depicts example currents for a temperature compensation circuit such as the temperature compensation circuit 133 of FIGS. 5B and 5C.

As shown in FIG. 8, as temperature increases the current of IREF_AMBIENT decreases to cause an increase in effective IREF1.

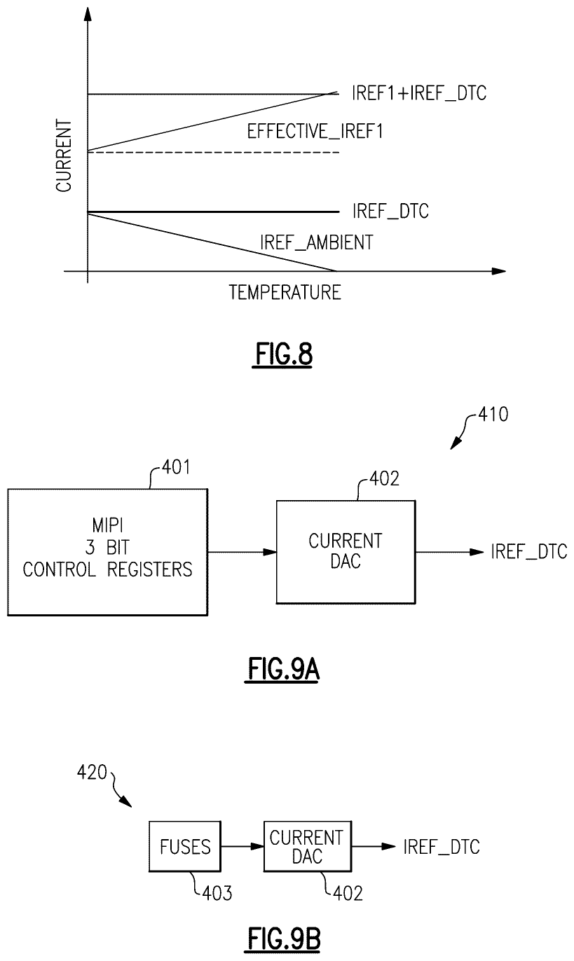

FIG. 9A is a schematic diagram of one embodiment of a reference current control circuit 410. The reference current control circuit 410 includes control registers 401 and a current digital-to-analog converter (DAC) 402 that serves as a controllable current source for generating the reference temperature compensation current IREF_DTC for a temperature compensation circuit.

In the illustrated embodiment, a mobile industry processor interface (MIPI) is used to set the value (3 bits, in this example) of the control registers 401 of the current DAC 402. Such a configuration allows for a stepped response for the reference temperature compensation current IREF_DTC.

Thus, the control registers 401 are allocated to allow tunability for the reference temperature compensation current IREF_DTC with the tuning bits providing a current range to work with. For example, the amount of current of the reference temperature compensation current IREF_DTC controls a sensitivity of a temperature compensation circuit to changes in temperature.

FIG. 9B is a schematic diagram of another embodiment of a reference current control circuit 420. The reference current control circuit 420 includes control registers 401 and a current DAC 402 that serves as a controllable current source for generating the reference temperature compensation current IREF_DTC for a temperature compensation circuit.

In the illustrated embodiment, the fuses 403 allow for non-volatile storage of bits that sets the current level of the reference temperature compensation current IREF_DTC.

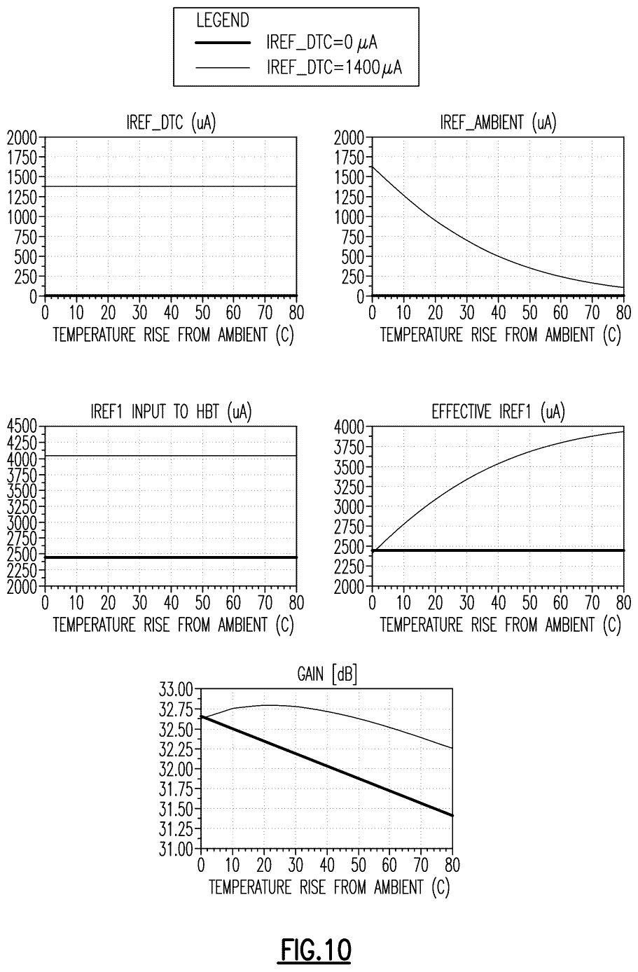

FIG. 10 depicts examples of various graphs of temperature dependent characteristics for two levels of the reference temperature compensation current IREF_DTC.

The graphs include a first set of plots for IREF_DTC=0 μA and a second set of plots for IREF_DTC=1400 μA. Graphs are shown for IREF_DTC, IREF_AMBIENT, IREF1 input to HBT, effective IREF1, and gain. The temperature is expressed as the temperature difference (ΔT) between ambient and the power amplifier transistor array.

As shown in FIG. 10, dynamic temperature compensation flattens the gain versus temperature characteristic of the power amplifier.

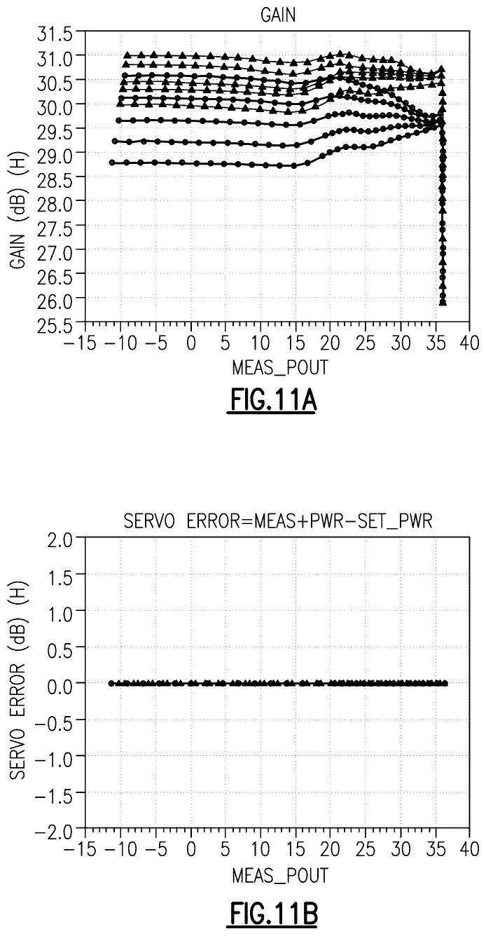

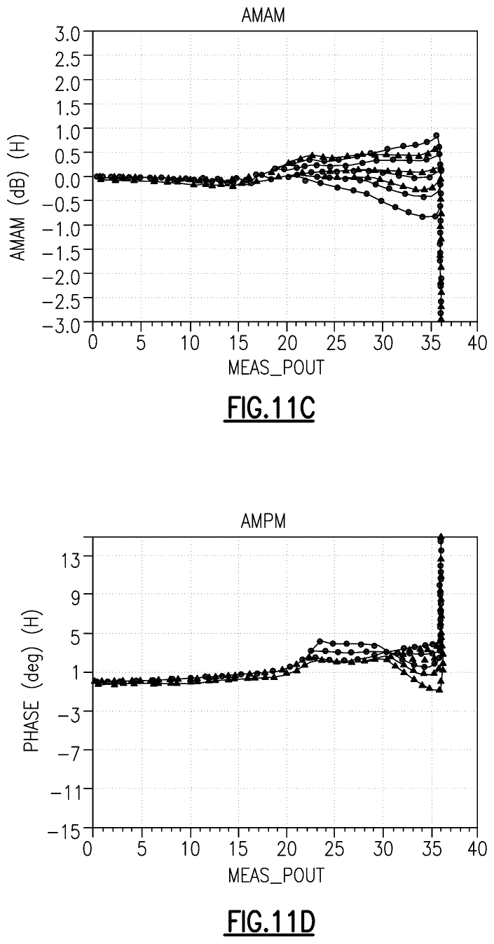

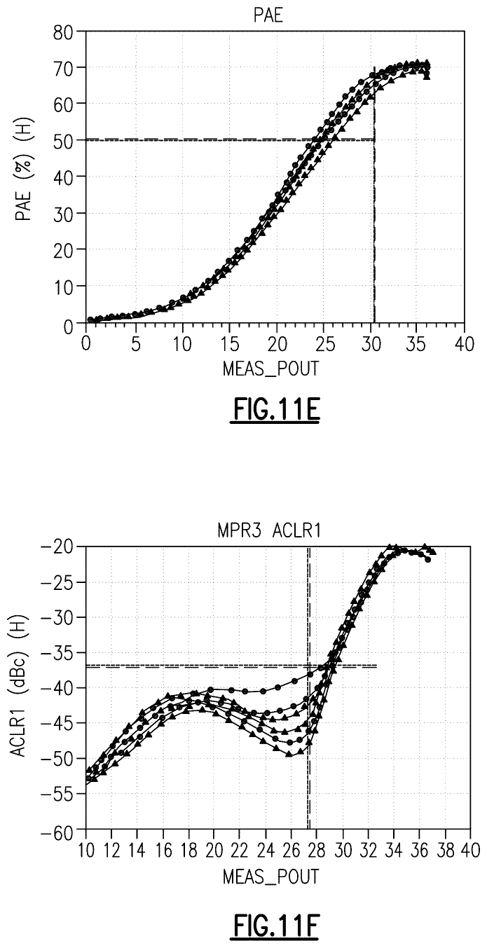

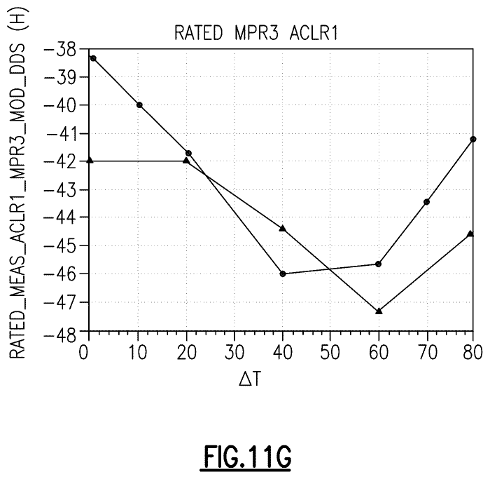

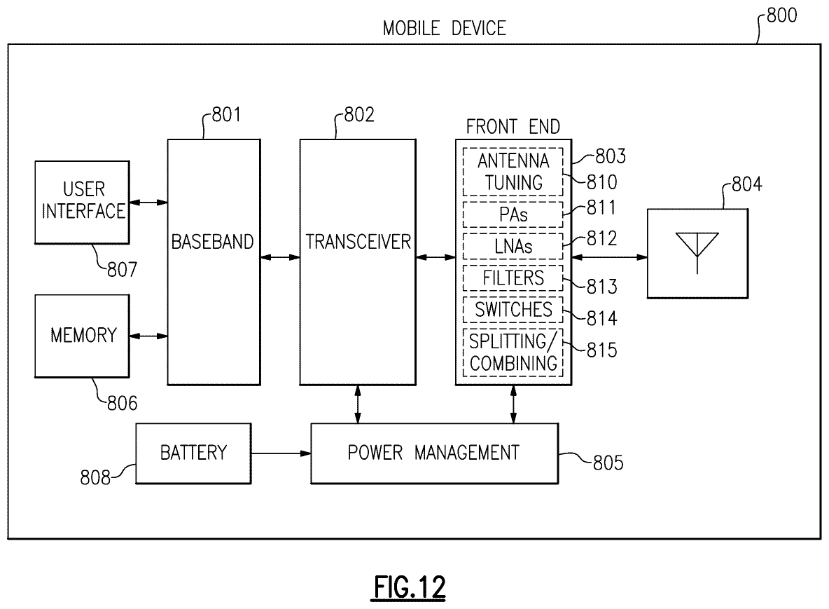

FIG. 11A depicts one example of gain versus measured output power for a power amplifier. FIG. 11B depicts one example of servo error versus measured output power for a power amplifier. FIG. 11C depicts one example of amplitude distortion (AMAM) versus measured output power for a power amplifier. FIG. 11D depicts one example of phase versus measured output power for a power amplifier. FIG. 11E depicts one example of power added efficiency (PAE) versus measured output power for a power amplifier. FIG. 11F depicts one example of adjacent channel leakage ratio (ALCR1) versus measured output power for a power amplifier. FIG. 11G depicts one example of maximum power reduction (MPR3) and ACLR1 versus temperature difference.

With reference to FIGS. 11A to 11G, various power amplifier performance parameters are shown with and without DTC (as well as with varying levels of DTC in certain graphs). As shown in the graphs, power amplifier gain variation tightens up across temperature when using DTC. Further, such benefits are achieved without trading off PAE. Moreover, ACLR is improved across temperature.

FIG. 12 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, Wi-Fi®), WPAN (for instance, Bluetooth® and ZigBee®), WMAN (for instance, WiMax®), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 12 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAs) 811, low noise amplifiers (LNAs) 812, filters 813, switches 814, and signal splitting/combining circuitry 815. However, other implementations are possible.

For example, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 12, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 12, the power management system 805 receives a battery voltage from the battery 808. The battery 808 can be any suitable battery for use in the mobile device 800, including, for example, a lithium-ion battery.

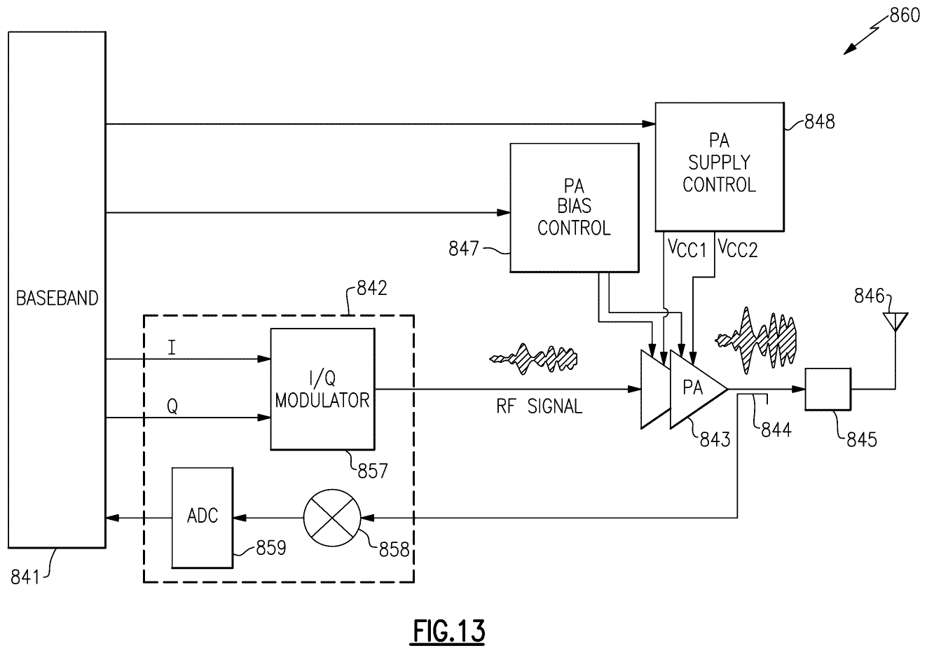

FIG. 13 is a schematic diagram of a power amplifier system 860 according to one embodiment. The illustrated power amplifier system 860 includes a baseband processor 841, a transmitter/observation receiver 842, a power amplifier (PA) 843, a directional coupler 844, front-end circuitry 845, an antenna 846, a PA bias control circuit 847, and a PA supply control circuit 848. The illustrated transmitter/observation receiver 842 includes an I/Q modulator 857, a mixer 858, and an analog-to-digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/Q modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 841 can be included in the power amplifier system 860.

The I/Q modulator 857 can be configured to receive the I and Q signals from the baseband processor 841 and to process the I and Q signals to generate an RF signal. For example, the I/Q modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the power amplifier 843. In certain implementations, the I/Q modulator 857 can include one or more filters configured to filter frequency content of signals processed therein.

The power amplifier 843 can receive the RF signal from the I/Q modulator 857, and when enabled can provide an amplified RF signal to the antenna 846 via the front-end circuitry 845.

The front-end circuitry 845 can be implemented in a wide variety of ways. In one example, the front-end circuitry 845 includes one or more switches, filters, duplexers, multiplexers, and/or other components. In another example, the front-end circuitry 845 is omitted in favor of the power amplifier 843 providing the amplified RF signal directly to the antenna 846.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841. Including a feedback path from the output of the power amplifier 843 to the baseband processor 841 can provide a number of advantages. For example, implementing the baseband processor 841 in this manner can aid in providing power control, compensating for transmitter impairments, and/or in performing digital pre-distortion (DPD). Although one example of a sensing path for a power amplifier is shown, other implementations are possible.

The PA supply control circuit 848 receives a power control signal from the baseband processor 841, and controls supply voltages of the power amplifier 843. In the illustrated configuration, the PA supply control circuit 848 generates a first supply voltage V_{CC1} for powering an input stage of the power amplifier 843 and a second supply voltage V_{CC2} for powering an output stage of the power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation.

One technique for improving efficiency of a power amplifier is average power tracking (APT), in which a DC-to-DC converter is used to generate a supply voltage for a power amplifier based on the power amplifier's average output power. Another technique for improving efficiency of a power amplifier is envelope tracking (ET), in which a supply voltage of the power amplifier is controlled in relation to the envelope of the RF signal. Thus, when a voltage level of the envelope of the RF signal increases the voltage level of the power amplifier's supply voltage can be increased. Likewise, when the voltage level of the envelope of the RF signal decreases the voltage level of the power amplifier's supply voltage can be decreased to reduce power consumption.

In certain configurations, the PA supply control circuit 848 is a multi-mode supply control circuit that can operate in multiple supply control modes including an APT mode and an ET mode. For example, the power control signal from the baseband processor 841 can instruct the PA supply control circuit 848 to operate in a particular supply control mode.

As shown in FIG. 13, the PA bias control circuit 847 receives a bias control signal from the baseband processor 841, and generates bias control signals for the power amplifier 843. In the illustrated configuration, the bias control circuit 847 generates bias control signals for both an input stage of the power amplifier 843 and an output stage of the power amplifier 843. However, other implementations are possible.

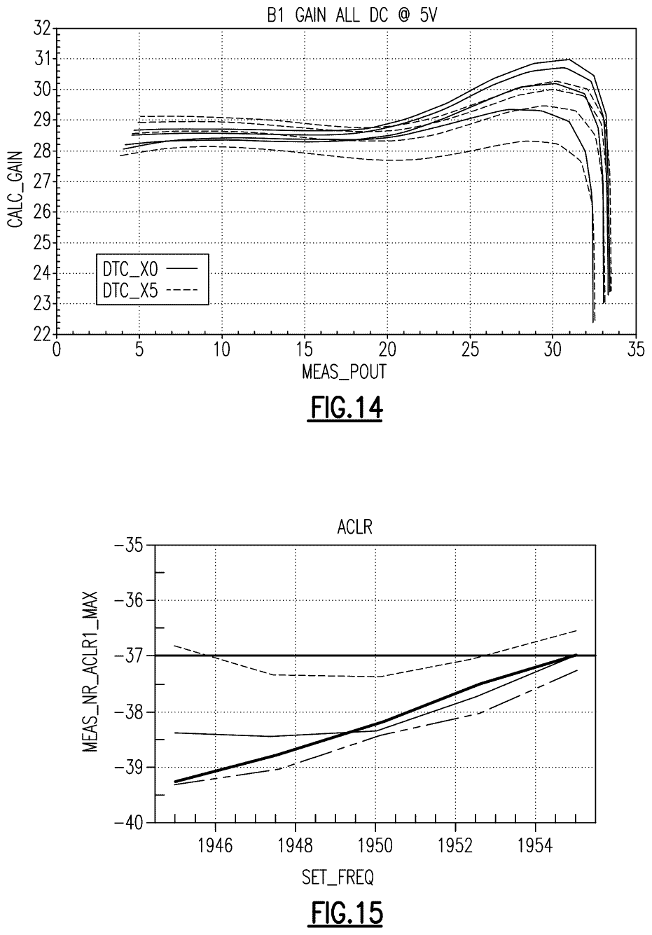

FIG. 14 is a graph of one example of measured gain versus output power for various duty cycles with and without DTC. As shown by the graph, the gain curves show sag (and corresponding AMAM) without DTC, particularly at higher duty cycles.

By using DTC, a reduction in the sag and a corresponding improvement in AMAM are achieved.

FIG. 15 is a graph of one example of plots of measured ALCR1 versus frequency for varying levels of DTC.

As shown in FIG. 15, an improvement in ALCR1 is achieved by increasing DTC.

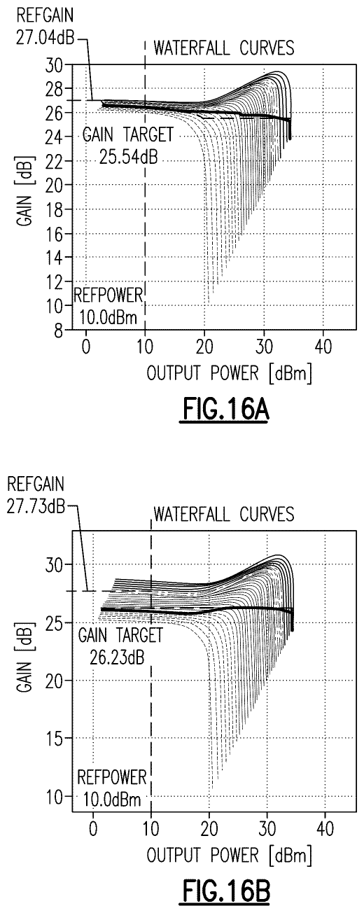

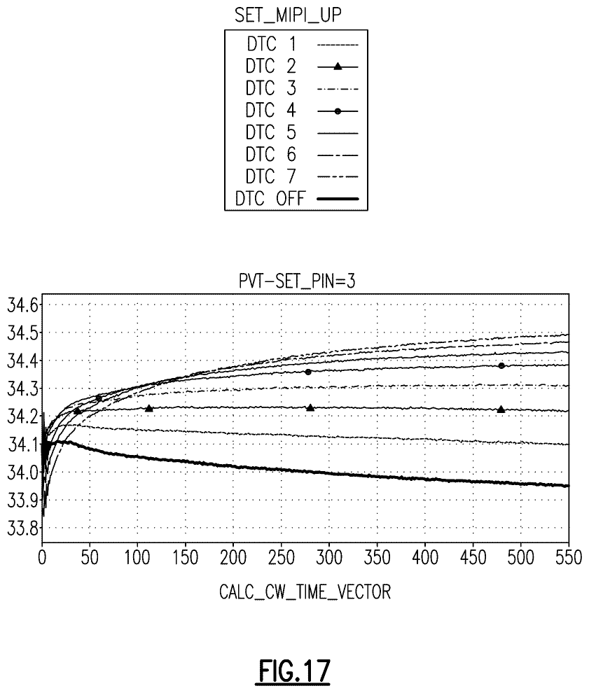

FIG. 16A is one example of a set of waterfall curves of gain versus output power without DTC. FIG. 16B is one example of a set of waterfall curves of gain versus output power with DTC.

The variation in gain versus power supply voltage (VCC) is desired and is referred to as gain dispersion. DTC helps to achieve positive gain dispersion since final devices temperature increases with VCC, which is captured by a hot VCC device and increases the gain of the driver stage. It is desirable to avoid banana shapes in AMAM and higher gain compression at higher powers.

As shown by a comparison of FIG. 16A and FIG. 16B, the waterfall curves associated with using DTC exhibit improved performance, including superior gain dispersion.

FIG. 17 is a graph of one example of power versus time for various DTC levels.

As shown in FIG. 17, changing the level of DTC adjusts the flatness of the power versus time response. Accordingly, a suitable amount of DTC can be used to achieve a substantially flat power versus time performance characteristic.

### Applications

Some of the embodiments described above have provided examples in connection with mobile devices. However, the principles and advantages of the embodiments can be used for any other systems or apparatus that have needs for power amplifier systems. Examples of such RF communication systems include, but are not limited to, mobile phones, tablets, base stations, network access points, customer-premises equipment (CPE), laptops, and wearable electronics.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier comprising:
one or more power amplifier stages configured to amplify a radio frequency signal, the one or more power amplifier stages including a transistor array;
a bias circuit configured to generate a bias signal that biases at least one power amplifier stage of the power amplifier stages; and
a temperature compensation circuit including a first bipolar transistor configured to operate at an ambient temperature and a second bipolar transistor configured to operate at a temperature of the transistor array, the temperature compensation circuit configured to adjust the bias signal based on a temperature difference between the first bipolar transistor and the second bipolar transistor.

2. The power amplifier of claim 1 wherein a base of the first bipolar transistor is electrically connected to a base and a collector of the second bipolar transistor at a node, and a collector of the first bipolar transistor is configured to provide a compensation current to the bias circuit.

3. The power amplifier of claim 2 wherein the temperature compensation circuit further includes a current source configured to provide a reference temperature compensation current to the node.

4. The power amplifier of claim 3 wherein the reference temperature compensation current is controllable.

5. (canceled)

6. The power amplifier of claim 2 wherein the temperature compensation circuit further includes a low pass filter electrically connected to the node.

7. The power amplifier of claim 1 wherein the one or more power amplifier stages includes an input stage that is biased by the bias signal and an output stage that includes the transistor array.

8. The power amplifier of claim 1 wherein the first bipolar transistor and the second bipolar transistor are formed on a common semiconductor die and separated by at least 300 μm.

9. The power amplifier of claim 1 wherein the first bipolar transistor and the second bipolar transistor are formed on a common semiconductor die attached to a module substrate, and a layout of the first bipolar transistor is cooled by drawing heat through a separate electrical connection to the module substrate.

10. The power amplifier of claim 1 wherein the bias circuit includes a bias input node electrically connected to a collector of the first bipolar transistor, a reference bias current source configured to provide a reference bias current to the bias input node, and a first bias bipolar transistor having a base electrically connected to the bias input node and an emitter configured to generate the bias signal.

11. The power amplifier of claim 10 wherein a collector current of the first bipolar transistor is configured to adjust the reference bias current based on the temperature difference.

12. The power amplifier of claim 10 wherein the bias circuit further includes a second bias bipolar transistor having a collector connected to the bias input node and an emitter electrically connected to a ground voltage, and a diode electrically connected between the bias input node and a base of the second bias bipolar transistor.

13. The power amplifier of claim 1 wherein the one or more power amplifier stages include a plurality of power amplifier stages arranged in a cascade.

14. The power amplifier of claim 1 wherein the one or more power amplifier stages include a plurality of power amplifier stages arranged as a push-pull power amplifier.

15. The power amplifier of claim 1 wherein a layout of the second bipolar transistor is integrated into a layout of the transistor array.

16. A mobile device comprising:
a transceiver configured to generate a radio frequency signal; and
a front-end system including a power amplifier that includes one or more power amplifier stages configured to amplify the radio frequency signal, a bias circuit configured to generate a bias signal that biases at least one power amplifier stage of the power amplifier stages, and a temperature compensation circuit including a first bipolar transistor configured to operate at an ambient temperature and a second bipolar transistor configured to operate at a temperature of a transistor array of the one or more power amplifier stages, the temperature compensation circuit configured to adjust the bias signal based on a temperature difference between the first bipolar transistor and the second bipolar transistor.

17. The mobile device of claim 16 wherein a base of the first bipolar transistor is electrically connected to a base and a collector of the second bipolar transistor at a node, and a collector of the first bipolar transistor is configured to provide a compensation current to the bias circuit.

18. The mobile device of claim 17 wherein the temperature compensation circuit further includes a current source configured to provide a reference temperature compensation current to the node.

19-23. (canceled)

24. The mobile device of claim 16 wherein the first bipolar transistor and the second bipolar transistor are formed on a common semiconductor die attached to a module substrate, and a layout of the first bipolar transistor is cooled by drawing heat through a separate electrical connection to the module substrate.

25-31. (canceled)

32. A method of radio frequency signal amplification in a mobile device, the method comprising:
amplifying a radio frequency signal using one or more power amplifier stages of a power amplifier, the one or more power amplifier stages including a transistor array;
generating a bias signal that biases at least one power amplifier stage of the power amplifier stages using a bias circuit of the power amplifier;
operating a first bipolar transistor of a temperature compensation circuit of the power amplifier at an ambient temperature, and operating a second bipolar transistor of the power amplifier at a temperature of the transistor array; and
adjusting the bias signal based on a temperature difference between the first bipolar transistor and the second bipolar transistor using the temperature compensation circuit.

33. The method of claim 32 wherein a base of the first bipolar transistor is electrically connected to a base and a collector of the second bipolar transistor at a node, the method further comprising providing a compensation current to the bias circuit from a collector of the first bipolar transistor.

34-47. (canceled)
